(19) United States
(12) Patent Application Publication
(10) Pub. No.: US 2026/0172758 A1
(43) Pub. Date: Jun. 18, 2026

(54) MICROELECTROMECHANICAL LOUDSPEAKER

(71) Applicant: Robert Bosch GmbH, Stuttgart (DE)

(72) Inventors: Andreas Winden, Reutlingen (DE); Peter Engelhart, St. Johann (DE); Stefan Pinter, Reutlingen (DE)

(21) Appl. No.: 19/125,391

(22) PCT Filed: Nov. 6, 2023
(86) PCT No.: PCT/EP2023/080796

§ 371 Date: Jul. 21, 2025

(30) Foreign Application Priority Data
Nov. 11, 2022 (DE) 10 2022 212 004.3

(51) Int. Cl. H04R 19/02; B81B 3/00; H04R 1/02

(52) U.S. Cl. CPC H04R 19/02; B81B 3/0021; H04R 1/025; B81B 2201/0257; B81B 2203/0136; B81B 2203/0163; B81B 2203/04; H04R 2201/003; H04R 2400/11

(57) ABSTRACT

A microelectromechanical loudspeaker. The loudspeaker includes: a housing structure; a displacement plate, which is mounted in the housing structure such that it can be deflected along a deflection direction; and an actuator structure, which is connected to the displacement plate for deflecting the displacement plate along the deflection direction, wherein the actuator structure includes at least two actuator planes which are resiliently connected to one another and disposed one above the other in the deflection direction, wherein, on facing plane surfaces, the actuator planes include electrode units, and wherein the electrode units can be activated to move the actuator planes relative to one another along the deflection direction and the displacement plate can be deflected along the deflection direction via the movement of the actuator planes.

### FIELD

The present invention relates to a microelectromechanical loudspeaker.

### BACKGROUND INFORMATION

A wide variety of microelectromechanical loudspeakers are described in the related art.

### SUMMARY

It is an object of the present invention to provide an improved microelectromechanical loudspeaker.

This object is achieved by the microelectromechanical loudspeaker according to certain features of the present invention. Advantageous configurations of the present invention are disclosed herein.

According to one aspect of the present invention, a microelectromechanical loudspeaker is provided. According to an example embodiment of the present invention, the loudspeaker includes:

a housing structure;

a displacement plate, which is mounted in the housing structure such that it can be deflected along a deflection direction; and an actuator structure, which is connected to the displacement plate for deflecting the displacement plate along the deflection direction, wherein the actuator structure comprises at least two actuator planes which are resiliently connected to one another and disposed one above the other in the deflection direction, wherein, on facing plane surfaces, the actuator planes comprise electrode units, and wherein the electrode units can be activated to move the actuator planes relative to one another along the deflection direction and the displacement plate can be deflected along the deflection direction via the movement of the actuator planes.

This makes it possible to achieve the technical advantage that an improved microelectromechanical loudspeaker can be provided. The loudspeaker comprises a displacement plate for generating the sound waves. The displacement plate can be deflected in the direction of a deflection direction via an actuator structure. The actuator structure here comprises at least two actuator planes which are resiliently connected to one another and on which electrode units are disposed. The electrode units can be activated to move the resiliently connected actuator planes relative to one another and thus deflect the displacement plate in order to generate the acoustic signals. The actuator planes, which are disposed stacked one above the other along the deflection direction, and the activation of the electrode units make it possible to produce a precise deflection of the displacement plate. This enables extremely precise control of the microelectromechanical loudspeaker. The actuator planes can be moved toward or away from one another by electrically charging the facing electrode units of the actuator planes disposed one above the other. The displacement plate can thus be set to vibrate accordingly in order to generate the acoustic signals. The resilient connection of the two actuator planes enables them to move back to a zero position immediately after activation of the electrode units.

The serial mechanical coupling of the individual actuator units moreover makes it possible to achieve multiple deflections of the entire actuator structure. For this purpose, the individual deflections of the individual actuator planes are added together to the total deflection of the entire actuator structure. The total deflection can be mechanically transmitted directly to the displacement plate.

According to one example embodiment of the present invention, the housing structure further comprises an outlet opening which is disposed opposite to the displacement plate.

This makes it possible to achieve the technical advantage of optimum radiation of the sound signals of the displacement plate from the outlet opening into the surroundings of the loudspeaker.

According to one example embodiment, at least one actuator plane is configured as a flat plate, in which case the electrode unit is configured as an electrode surface.

This makes it possible to achieve the technical advantage that the greatest possible electrical interaction between the facing electrode units can be realized by configuring the electrode units as an electrode surface. This enables precise control of the actuator structure and, consequently, of the loudspeaker.

According to one example embodiment of the present invention, the electrode unit comprises at least one electrode projection element which projects from the plane surface along the deflection direction.

This makes it possible to achieve the technical advantage that a surface of the electrode unit can be increased by the electrode projection elements of the electrode units. This increases the electrical interaction between the facing electrode units of the actuator planes. The projection of the electrode projection elements moreover allows the distance between the electrode unit and the respective opposite actuator plane to be reduced, which further improves the electrical interaction and with it the precision of control.

According to one example embodiment of the present invention, the electrode units of the at least two actuator planes each comprise a plurality of electrode projection elements which are disposed in comb structures, and wherein the comb structures of the actuator planes are able to engage with one another.

This makes it possible to achieve the technical advantage that the electrical interaction between the electrode units of the actuator planes can be further improved by configuring the electrode projection elements in comb structures and by the engagement of the comb structures of the oppositely disposed actuator planes. The engagement of the comb structures of the electrode units of the oppositely disposed actuator planes makes it possible to reduce the distances between the facing electrode units. This further increases the electrical interaction and with it the actuation of the actuator structure.

According to one example embodiment of the present invention, the electrode projection elements are configured as linear comb elements.

This makes it possible to achieve the technical advantage that the surface of the electrode units can be increased by the linear configuration of the electrode projection elements. This in turn leads to a further increase in the electrical interaction between facing electrode units.

According to one example embodiment of the present invention, the comb elements of an actuator plane extend in at least two extension directions which each have an angle to one another.

This makes it possible to achieve the technical advantage that a displacement of two adjacent actuator planes in a displacement direction perpendicular to the deflection direction can be prevented by extending the electrode projection elements of an electrode unit configured as linear comb elements in extension directions having an angle to one another. The actuator planes are thus deflected exclusively in the deflection direction. It can thus be achieved that the displacement plate is likewise deflected exclusively in the deflection direction. This enables extremely precise control of the actuator structure.

According to one example embodiment of the present invention, at least one actuator plane comprises a spacer frame which is configured on an outer edge of the actuator plane, wherein the actuator plane is resiliently connected to the respective other actuator plane via at least one spring element configured on the spacer frame.

This makes it possible to achieve the technical advantage that the rigidity of the actuator plane can be increased by means of the spacer frame. Vibrations within the actuator planes can thus be reduced or avoided. This then can increase the precision of the control of the actuator structure. The spring element enables the simplest possible technical solution for a resilient connection between two adjacent actuator planes. Configuring the spring element on the spacer frame makes it possible to ensure that the entire surface of the respective actuator plane can be used to form the electrode unit.

According to one example embodiment of the present invention, the actuator plane is rectangular, in which case a spring element is configured on each side edge of the actuator plane.

This makes it possible to achieve the technical advantage a uniform spring-loaded connection between two adjacent actuator planes can be achieved by configuring the spring elements on all side edges of the actuator plane. This prevents tilting of the adjacent actuator planes relative to one another, which enables precise control of the actuator structure. Controlling adjacent electrode units makes it possible to move adjacent actuator planes relative to one another uniformly.

According to one example embodiment of the present invention, the actuator planes have different dimensions and are disposed in a pyramidal arrangement along the deflection direction, wherein the spring elements are disposed laterally on the side edges and can be deflected in the deflection direction and perpendicular to the deflection direction.

This makes it possible to achieve the technical advantage that the pyramidal arrangement of the differently dimensioned actuator planes enables a configuration of the actuator structure with the greatest possible saving of material and thus a weight-saving configuration of the loudspeaker. The pyramidal arrangement also allows the spring elements to be configured laterally on the side edges of the actuator planes. The spring elements can then be deflected exclusively in the deflection direction and deflection of the actuator planes perpendicular to the deflection direction can be avoided. This enables as precise a control of the actuator structure as possible, in which vibrations of the actuator plane perpendicular to the deflection direction can be avoided.

According to one example embodiment of the present invention, the spacer frame comprises a spacer element which extends along the deflection direction.

This makes it possible to achieve the technical advantage that the spacer element can enable the resilient connection to an adjacent deflection plane by means of the spring elements. A distance between adjacent deflection planes in an undeflected position of the two deflection planes can be defined by means of the spacer element. This enables a predefined vibration path of the adjacent deflection planes relative to one another and with it precise control of the deflection structure.

According to one example embodiment of the present invention, the loudspeaker further comprises:

a frame structure, wherein the frame structure forms a receiving space, wherein the displacement surface and the actuator structure are disposed in the receiving space, and wherein an actuator plane is connected to the frame structure via at least one spring element.

This makes it possible to achieve the technical advantage that a stable configuration of the loudspeaker is provided by means of the frame structure. The lack of a connection between at least one actuator plane and the frame structure furthermore allows the frame structure to be used as a reference structure for the vibrations of the actuator structure or the displacement plate. This again enables the actuator structure and with it the loudspeaker to be controlled as precisely as possible.

According to one example embodiment of the present invention, an actuator plane is formed by a surface of a bottom region of the frame structure.

This makes it possible to achieve the technical advantage that the actuator structure can be configured in the most space-saving way possible.

According to one example embodiment of the present invention, an air gap is formed between an outer edge region of the displacement plate and wall elements of the frame structure.

This makes it possible to achieve the technical advantage that pressure equalization is enabled by the air gap, so that negative pressure caused by the vibrations of the actuator planes of the actuator structure or the displacement plate within the receiving space, which would negatively affect the control of the displacement plate, can be avoided.

According to one example embodiment of the present invention, a respective through-opening is configured in at least one actuator plane and/or the bottom region of the frame structure.

This makes it possible to achieve the technical advantage that pressure equalization can be achieved by means of the through-openings as well, which again leads to greater precision in the control of the actuator structure and with it the loudspeaker.

According to one example embodiment of the present invention, the displacement plate is connected to one of the actuator planes via a connecting projection which extends along the deflection direction, wherein a distance between the vibration plate and the actuator plane is defined via a length of the connecting projection.

This makes it possible to achieve the technical advantage that a secured connection between the displacement plate and the actuator structure is enabled. Due to the defined distance between the respective actuator plane and the displacement plate, the transmission of vibrations between the displacement plate and the actuator plane can be reduced to a minimum.

According to one example embodiment of the present invention, a bonded cabling is configured on the frame structure.

This makes it possible to achieve the technical advantage that a space-saving configuration of the bonded cabling is enabled.

Embodiment examples of the present invention are explained with reference to the figures.

### BRIEF DESCRIPTION OF THE DRAWINGS

FIG. 1 shows a schematic sectional view of a micromechanical loudspeaker according to one example embodiment of the present invention.

FIG. 2 shows a further schematic sectional view of the micromechanical loudspeaker in FIG. 1.

FIG. 3 shows a further schematic sectional view and a plan view of the micromechanical loudspeaker in FIG. 1.

FIG. 4 shows a further schematic sectional view and a further plan view of the micromechanical loudspeaker in FIG. 1.

FIG. 5 shows a further schematic sectional view and a further plan view of the micromechanical loudspeaker in FIG. 1.

FIG. 6 shows a further schematic sectional view and a further plan view of the micromechanical loudspeaker in FIG. 1.

FIG. 7 shows a further schematic sectional view of a micromechanical loudspeaker according to another example embodiment of the present invention.

FIG. 8 shows a further schematic sectional view and a plan view of the micromechanical loudspeaker in FIG. 7.

FIG. 9 shows a further schematic sectional view and a further plan view of the micromechanical loudspeaker in FIG. 7.

FIG. 10 shows a further schematic sectional view and a further plan view of the micromechanical loudspeaker in FIG. 7.

FIG. 11 shows a further schematic sectional view of the micromechanical loudspeaker according to another example embodiment of the present invention.

FIG. 12 shows a further schematic sectional view and a further plan view of the micromechanical loudspeaker according to another example embodiment of the present invention.

### DETAILED DESCRIPTION OF EXAMPLE EMBODIMENTS

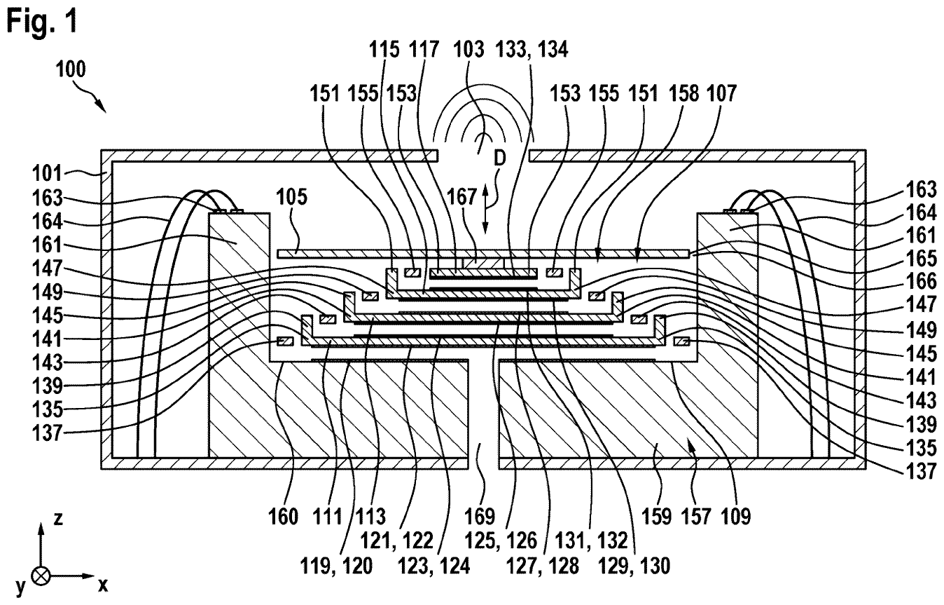

FIG. 1 shows a schematic sectional view of a micromechanical loudspeaker 100 according to one example embodiment of the present invention.

The microelectromechanical loudspeaker 100 comprises a housing structure 101 with an outlet opening 103 for providing acoustic signals. A displacement plate 105 disposed opposite to the outlet opening 103 and an actuator structure 107 connected to the displacement plate 105 are configured within the housing structure 101. The displacement plate 105 can be deflected along a deflection direction D via the actuator structure 107. The acoustic signals of the loudspeaker 100 can be generated via the deflection of the displacement plate 105.

The shown embodiment also includes a frame structure 157 configured inside the housing structure 101. The frame structure 157 comprises a bottom region 159 and wall elements 161. The frame structure 157 defines a receiving space 158 via the bottom region 159 and the wall elements 161.

In the shown embodiment, the displacement plate 105 and the actuator structure 107 connected to it are disposed in the receiving space 158.

Bond elements 163 with wiring 164 are furthermore configured on the wall elements 161 of the frame structure 157. The actuator structure 107 and with it the loudspeaker 100 can be electrically controlled via the bond elements 163 and the wiring 164.

According to the present invention, the actuator structure 107 comprises at least two actuator planes 109, 111, 113, 115, 117. The actuator planes 109, 111, 113, 115, 117 are disposed stacked one above the other along the deflection direction D and are resiliently connected to one another.

According to the present invention, the actuator planes 109, 111, 113, 115, 117 comprise electrode units 120, 122, 124, 126, 128, 130, 132, 134 configured on plane surfaces 119, 121, 123, 125, 127, 129, 131, 133. The electrode units 120, 122, 124, 126, 128, 130, 132, 134 are all electrically controllable and electrode units 120, 122, 124, 126, 128, 130, 132, 134 which are disposed opposite to one another can thus interact with one another via an electrical interaction. This can be used to move the actuator planes 109, 111, 113, 115, 117 relative to one another. The movement of the actuator planes 109, 111, 113, 115, 117 of the actuator structure 107 in opposite directions sets the displacement plate 105 in vibration along the deflection direction D. This can be used to generate the acoustic signals of the loudspeaker 100.

In the shown embodiment, the actuator structure 107 comprises five actuator planes 109, 111, 113, 115, 117.

A first actuator plane 109 is formed here by a bottom surface 160 of the bottom region 159 of the frame structure 157. A corresponding electrode unit 119 is configured on the bottom surface 160, which in this case forms a flat surface 119 of the actuator plane 109.

A further actuator plane 111 is disposed opposite and adjacent to the actuator plane 109. On a plane surface 121 disposed adjacent to the electrode unit 120 of the actuator plane 109, the actuator plane 111 comprises an electrode unit 122. The actuator plane 111 comprises a spacer frame 135. A plurality of spring elements 143 are disposed on the spacer frame 135. The actuator plane 111 is resiliently connected to the edge elements 161 of the frame structure 157 via the spring elements 143. Spacer elements 139 are also configured on the spacer frame 135. The spacer elements 139 are configured along the deflection direction D. Opposite to the plane surface 121, the actuator plane 111 comprises a further plane surface 123 with a further electrode unit 124.

A further actuator plane 113 is disposed adjacent to the actuator plane 111. On a plane surface 125 facing the actuator plane 111, the actuator plane 113 comprises a further electrode unit 126. The actuator plane 113 also comprises a spacer frame 141 with spacer elements 145. A plurality of spring elements 143 are disposed on the spacer frame 141. The actuator plane 113 is resiliently connected to the spacer elements 139 of the actuator plane 111 via the spring elements 143. On a plane surface 127 disposed opposite to the plane surface 125, the actuator plane 113 comprises a further electrode unit 128.

A further actuator plane 115 is disposed adjacent to the actuator plane 113. On a plane surface 129 facing the actuator plane 113, it comprises a further electrode unit 130. The actuator plane 115 also comprises a spacer frame 147 with spacer elements 151 which extend along the deflection direction D. Spring elements 149 are also configured on the spacer frame 147. The spring elements 149 connect the actuator plane 115 to the spacer elements 145 of the actuator plane 113. On a plane surface 131 disposed opposite to the plane surface 129, the actuator plane 115 comprises a further electrode unit 132.

A further actuator plane 117 is disposed adjacent to the actuator plane 115. On a plane surface 133 facing the actuator plane 115, it comprises a further electrode unit 134. The actuator plane 117 further comprises a spacer frame 153 on which spring elements 155 are disposed. The actuator plane 117 is resiliently connected to the spacer elements 151 of the actuator plane 115 via the spring elements 155.

The actuator plane 117 is also connected to the displacement plate 105 via a connecting projection 167.

Potential differences can be generated relative to one another on the actuator planes 109, 111, 113, 115, 117 of the actuator structure 107 by controlling the electrode unit 120, 122, 124, 126, 128, 130, 132, 134. Via the potential differences, the actuator planes 109, 111, 113, 115, 117 can be attracted to or repelled by one another. By resiliently connecting the actuator planes 109, 111, 113, 115, 117 via the respective spring elements, the actuator planes 109, 111, 113, 115, 117 of the actuator structure 107 can thus be set in vibration, as a result of which the displacement plate 105 in the receiving space 158 of the frame structure 157 can likewise be set in vibration along the deflection direction D.

In the shown embodiment, the actuator planes 109, 111, 113, 115, 117 are all configured as flat plates. The electrode units 120, 122, 124, 126, 128, 130, 132, 134 are all configured as electrode surfaces.

In the shown embodiment, the actuator planes 109, 111, 113, 115, 117 have different dimensions and are disposed in a pyramidal arrangement relative to one another. The spring elements 137, 143, 149 and 155 are all configured here on side regions of the actuator planes 111, 113, 115, 117. The spring elements 137, 143, 149, 155 can be deflected along the deflection direction D. The spring elements can further be configured such that deflection perpendicular to the deflection direction D is prevented, so that deflection of the actuator planes 111, 113, 115, 117 or the displacement plate 105 is possible only along the deflection direction D.

In the shown embodiment, the frame structure 157 further comprises a through-opening 169 in the bottom region 159. The through-opening extends into the receiving space 158 and passes through the actuator plane 109 with the electrode unit 120 configured on it.

On an edge region 165 in the receiving space 158, the displacement plate 105 also comprises an air gap 166 to elements 161 of the frame structure.

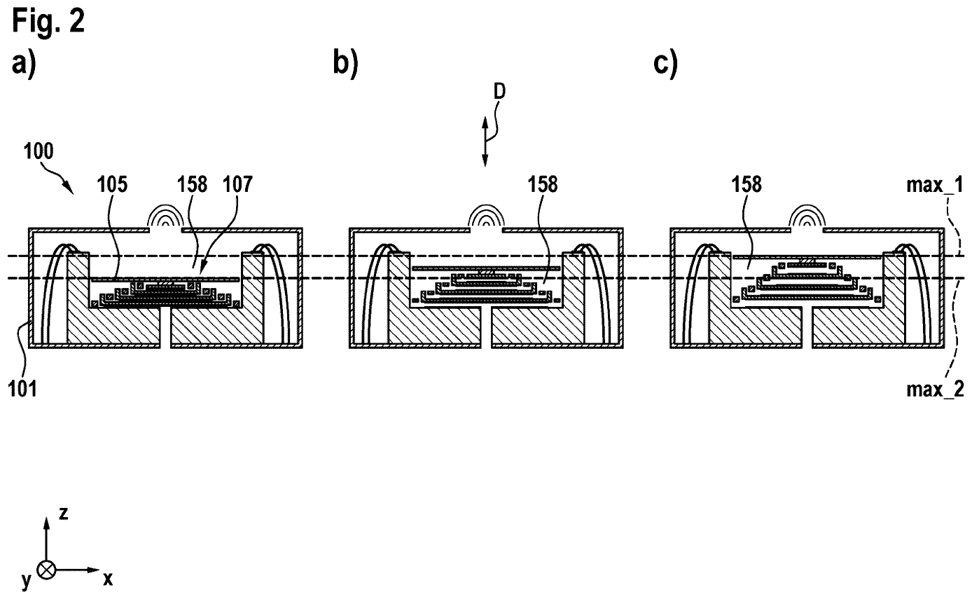

FIG. 2 shows a further schematic sectional view of the micromechanical loudspeaker 100 in FIG. 1.

Diagrams a) to c) show different deflections of the displacement plate 105 along the deflection direction D caused by controlling the actuator structure 107 in the receiving space 158 of the frame structure 157.

The shown embodiment of the microelectromechanical loudspeaker 100 is based on the embodiment of FIG. 1 and includes all of the features described there.

Diagrams a) to c) show the deflection of the displacement plate 105 between two maximum deflections max_1, max_2.

In diagram a), the structure 107 is fully contracted and the distances between the actuator planes 109, 111, 113, 115, 117 are minimized. As a result, the displacement plate 105 is drawn into the receiving space 158 to a maximum deflection max 2.

In diagram b), the actuator structure 107 is disposed in a zero position defined by the configuration of the spring elements and spacer elements of the individual actuator planes 109, 111, 113, 115, 117, in which the actuator structure 107 is shown as neither contracted nor expanded.

Diagram c) shows the deflection of the actuator structure 107 to a maximum deflection max_1, in which the actuator planes 109, 111, 113, 115, 117 are disposed at maximum spacing to one another.

The total stroke of the displacement plate 105 can be varied between the maximum deflections max_1 and max_2 via the number of actuator planes 109, 111, 113, 115, 117 of the actuator structure 107.

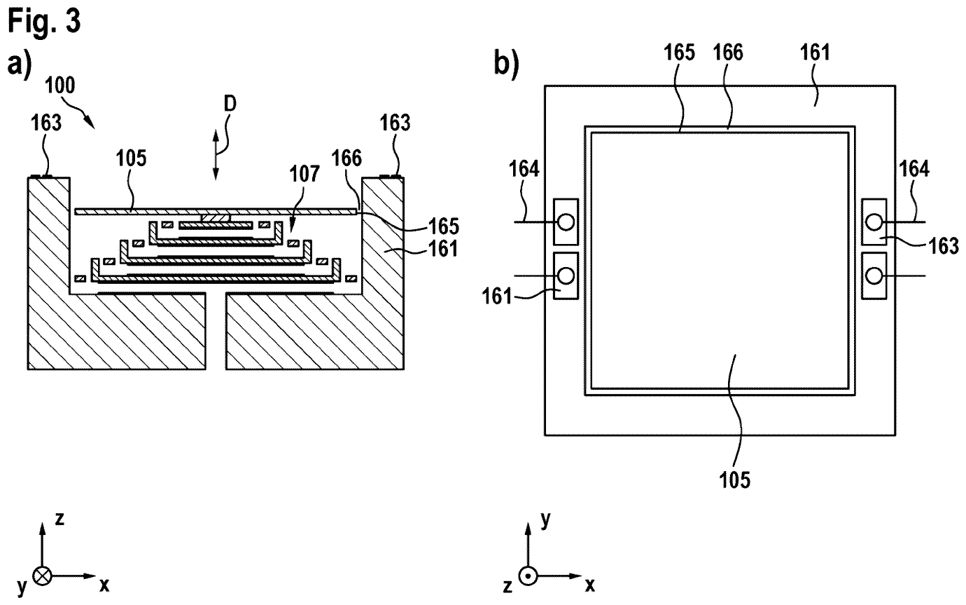

FIG. 3 shows a further schematic sectional view and a plan view of the micromechanical loudspeaker 100 in FIG. 1.

Diagram a) shows the sectional view of the sensor 100 in the embodiment in FIG. 1. To simplify the illustration of the embodiment in FIG. 1, diagram a) shows only the frame structure 157 with the actuator structure 107 configured in the receiving space 158 and the displacement plate 105 connected to it.

Diagram b) shows a plan view onto the displacement plate 105 disposed in the receiving space 158 of the frame structure 157. The frame structure 157 is cuboid and comprises four wall elements 161. In the shown embodiment, the displacement plate 105 is rectangular, in particular square, and is disposed in the receiving space 158. A uniform air gap 166 is formed between the edge regions 165 of the displacement plate 105 and the wall elements 161. Four bond elements 163, each with wiring 164, are also configured on the wall elements 161.

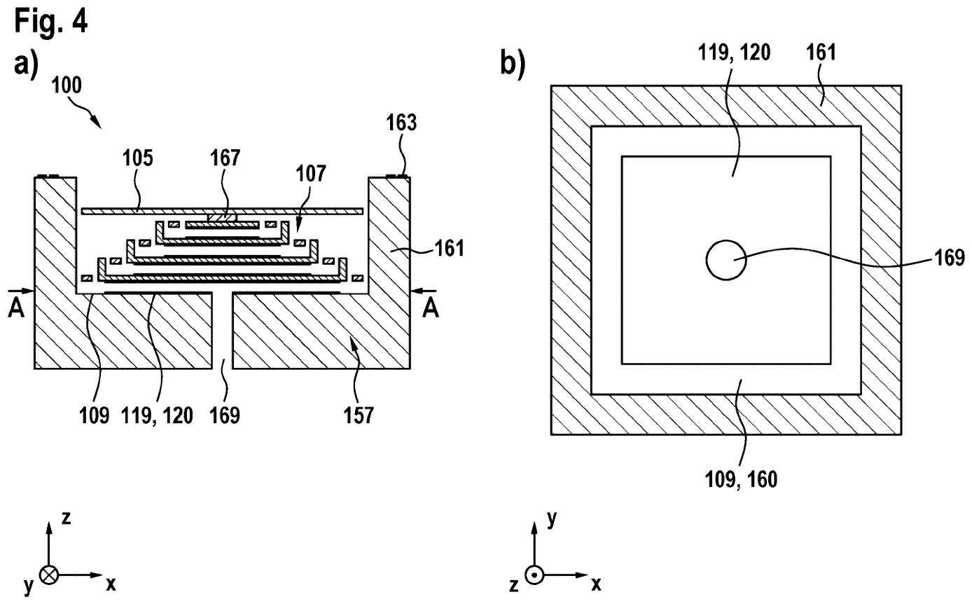

FIG. 4 shows a further schematic sectional view and a further plan view of the micromechanical loudspeaker 100 in FIG. 1.

Diagram a) shows the loudspeaker 100 of FIG. 3. Diagram b) shows a plan view of the sensor 100 on the sectional plane A of diagram a).

The shown actuator plane 109 is defined by the bottom surface 160 of the bottom region 159 of the frame structure 157. The actuator plane 109 is again rectangular or square. The electrode unit 120 is configured as an electrode surface with a square base. A circular through-opening 169 is configured centrally in the actuator plane 109 or the electrode unit 120 formed upon it.

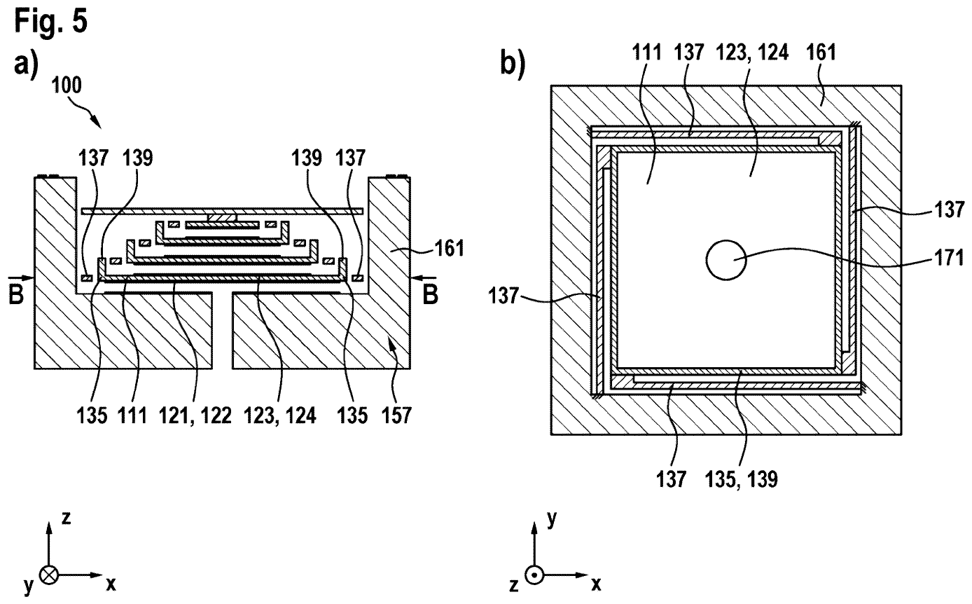

FIG. 5 show a further schematic sectional view and a further plan view of the micromechanical loudspeaker 100 in FIG. 1.

Diagram a) shows the loudspeaker 100 of the diagrams of FIGS. 3 and 4. Diagram b) shows a plan view onto the sectional plane B of diagram a).

The shown actuator plane 111 is rectangular or square. The electrode unit 124 on it is configured as an electrode surface with a square base. The actuator plane 111 comprises a surrounding spacer frame 135 with spacer elements 139 that extend along the z-axis of the depicted coordinate system. A spring element 137 is configured on each side of the square actuator plane 111 on the respective spacer frame 135. The spring element 137 is furthermore fixed to one of the four wall elements 161 of the frame structure 157. The actuator plane 111 again comprises a central circular through-opening 171.

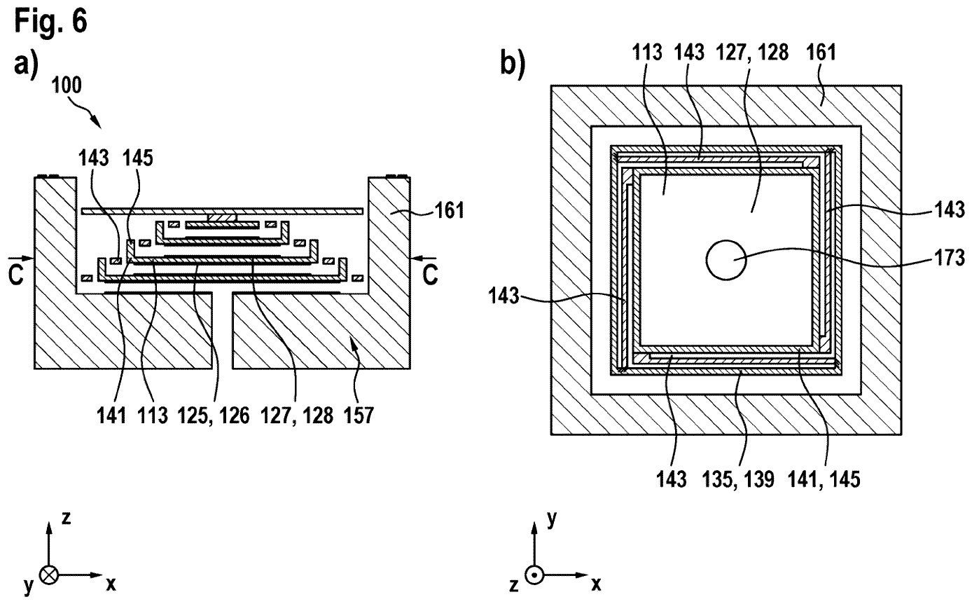

FIG. 6 shows a further schematic sectional view and a further plan view of the micromechanical loudspeaker 100 in FIG. 1.

Diagram a) again shows the sectional view of the loudspeaker 100 of the diagrams of FIGS. 3 to 5. Diagram b) shows a plan view onto the sectional plane C of diagram a).

The shown actuator plane 113 is rectangular or square. The electrode unit 128 disposed on it is configured as an electrode surface with a square base. A spacer frame 141 with spacer elements 145 that extend along the z-axis of the depicted coordinate system is configured along the four outer edges of the square actuator plane 113. The spacer frame 153 is also shown with the spacer elements 139 of the actuator plane 111 disposed below the actuator plane 113 in relation to the z-axis of the depicted coordinate system. A respective spring element 143 is configured on the spacer frame 141 on four side edges of the square actuator plane 113. The spring element 143 is respectively connected to the spacer frame 135, or the spacer elements 139 on it, of the actuator plane 111 which is disposed below the actuator plane 113 and is therefore not visible in diagram b). A circular through-opening 173 is again configured centrally within the actuator plane 113.

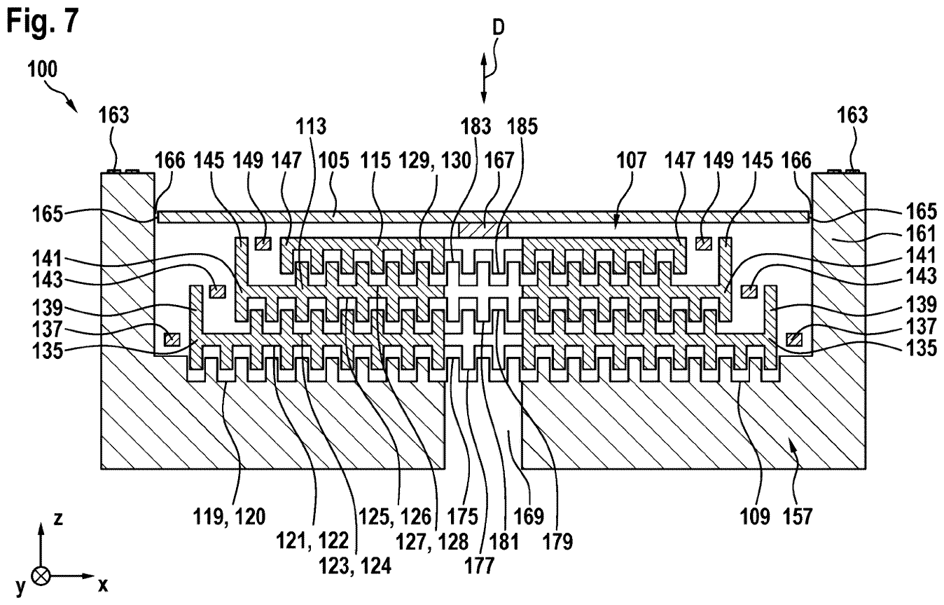

FIG. 7 shows a further schematic sectional view of a micromechanical loudspeaker 100 according to another embodiment.

The embodiment of the loudspeaker 100 shown in FIG. 7 is based on the embodiment in FIG. 1 and includes all of the features shown there. To simplify the illustration, the loudspeaker 100 is configured without the surrounding housing structure 101.

In contrast to the embodiment in FIG. 1, the actuator structure 107 comprises only four actuator planes 109, 111, 113, 115.

The actuator planes 109, 111, 113, 115 or the electrode units 120, 122, 124, 126, 128, 130 on them moreover comprise electrode projection elements 175, 177, 179, 181, 183, 185.

The electrode unit 120 thus comprises a plurality of electrode projection elements 175 which project from the actuator plane 109 or the plane surface 119 in the direction of the actuator plane 111 disposed above it.

The electrode unit 122 of the actuator plane 111 in turn comprises a plurality of electrode projection elements 177 that extend from the plane surface 121 of the actuator plane 111 in the direction of the actuator plane 109 disposed below it. The electrode unit 124 of the actuator plane 111 then likewise comprises a plurality of electrode projection elements 179 that extend from the plane surface 123 in the direction of the actuator plane 113 disposed above the actuator plane 111.

The electrode unit 126 of the actuator plane 113 in turn comprises a plurality of electrode projection elements 181 that extend from the respective plane surface 125 in the direction of the actuator plane 111 disposed below the actuator plane 113. The electrode unit 128 of the actuator plane 115 also comprises a plurality of electrode projection elements 183 that extend from the plane surface 127 in the direction of the actuator plane 115 disposed above the actuator plane 113.

The electrode unit 130 of the actuator plane 115 in turn comprises a plurality of electrode projection elements 185 that extend in the direction of the actuator plane 113 disposed below the actuator plane 115.

The electrode projection elements 175, 177, 179, 181, 183, 185 of the actuator planes 109, 111, 113, 115 are each configured in comb structures. The individual electrode projection elements 175, 177, 179, 181, 183, 185 are disposed such that the different comb structures of the different actuator planes 109, 111, 113, 115 can engage with one another.

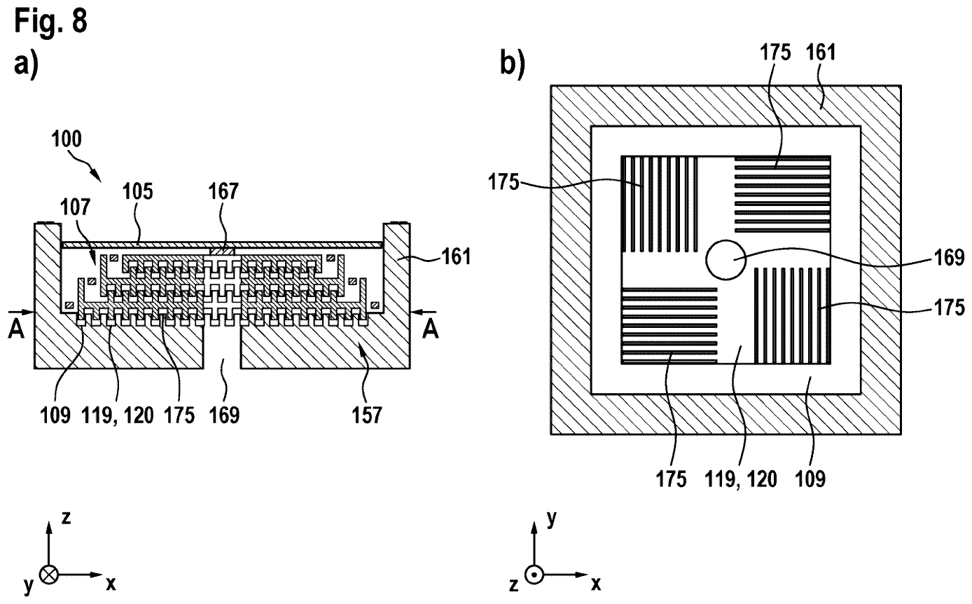

FIG. 8 shows a further schematic sectional view and a plan view of the micromechanical loudspeaker 100 in FIG. 7.

Diagram a) shows the loudspeaker 100 in the embodiment of FIG. 7. Diagram b) shows a plan view onto the sectional plane A of diagram a).

The embodiment of the shown actuator plane 109 is based on the embodiment of diagram b) in FIG. 4. In contrast to the embodiment in FIG. 4, the shown electrode unit 120 comprises the above-discussed plurality of electrode projection elements 175. In the shown embodiment, the electrode projection elements 175 are configured as line elements and extend along the x-direction or along the y-direction of the depicted coordinate system. The electrode projection elements 175 of the shown embodiment which are configured as line elements, are configured in four comb structures in which the respective electrode projection elements 175 are disposed parallel to one another.

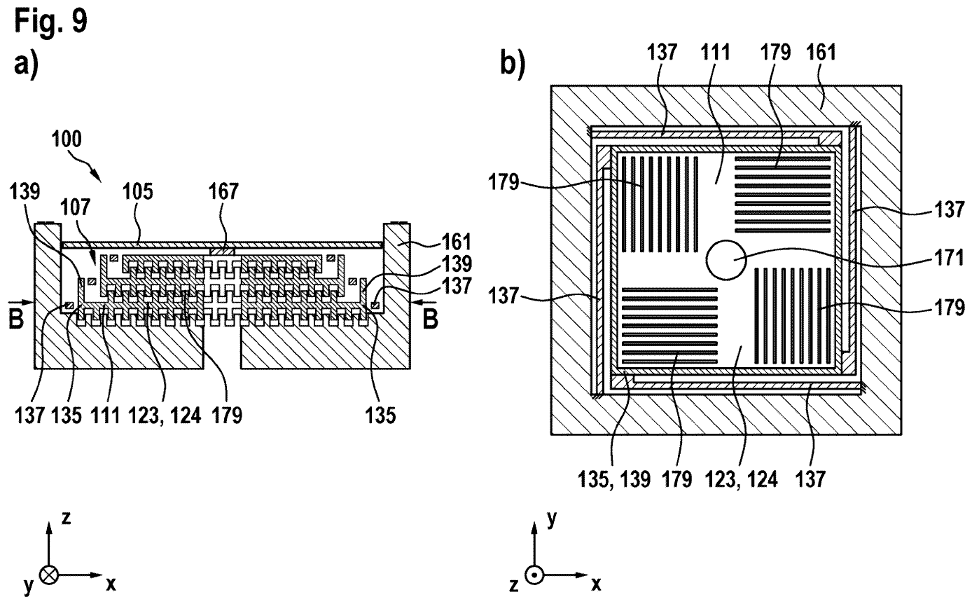

FIG. 9 shows a further schematic sectional view and a further plan view of the micromechanical loudspeaker 100 in FIG. 7.

Diagram a) shows the embodiment of diagram a) of FIG. 8. Like diagram b) of FIG. 5, diagram b) shows the plan view onto the sectional plane B of diagram a).

The shown actuator plane 111 is based on the embodiment in diagram b) of FIG. 5 and includes all of the features described there. Deviating from this, the electrode unit 124 comprises the above-discussed electrode projection elements 179. The arrangement of the electrode projection elements 179 corresponds to the arrangement of the electrode projection elements 175 of the electrode unit 120 of the actuator plane 109. The linearly configured electrode projection elements 179 are disposed in four comb structures, in which the linear electrode projection elements 179 are disposed parallel to one another. Various comb structures again extend along the x-or y-direction.

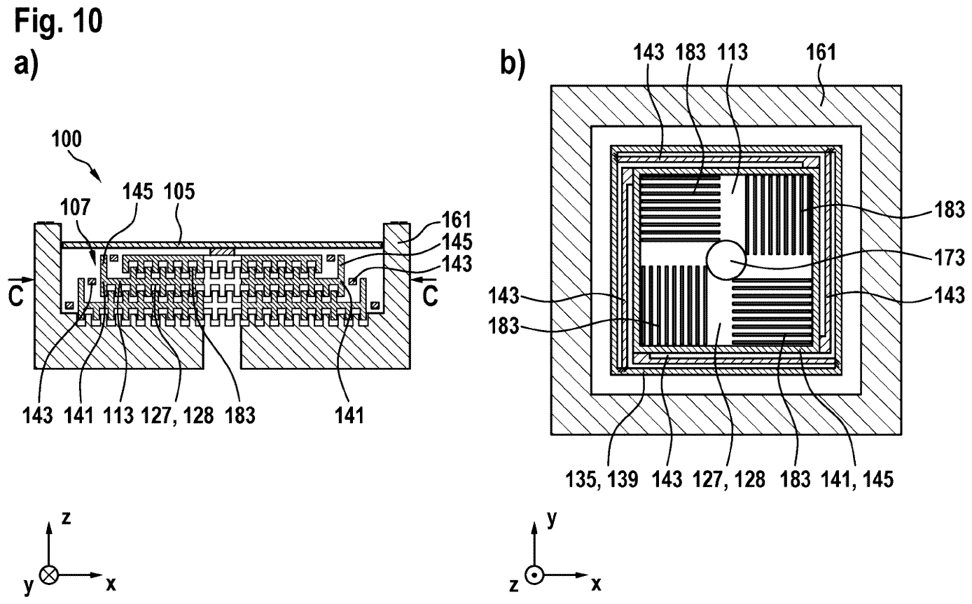

FIG. 10 shows a further schematic sectional view and a further plan view of the micromechanical loudspeaker 100 in FIG. 7.

Diagram a) is again based on diagram a) of FIGS. 8 and 9. Like diagram b) of FIG. 6, diagram b) shows a plan view onto the sectional plane C of diagram a).

The shown actuator plane 113 is based on the embodiment of diagram b) of FIG. 6 and includes all of the features described there. The shown electrode unit 128 comprises the above-discussed electrode projection elements 183. Analogous to the embodiments of FIGS. 8 and 9, the electrode projection elements 183 are disposed in four comb structures, in which the linear electrode projection elements 183 are respectively disposed such that they extend parallel along the directions x or y of the depicted coordinate system.

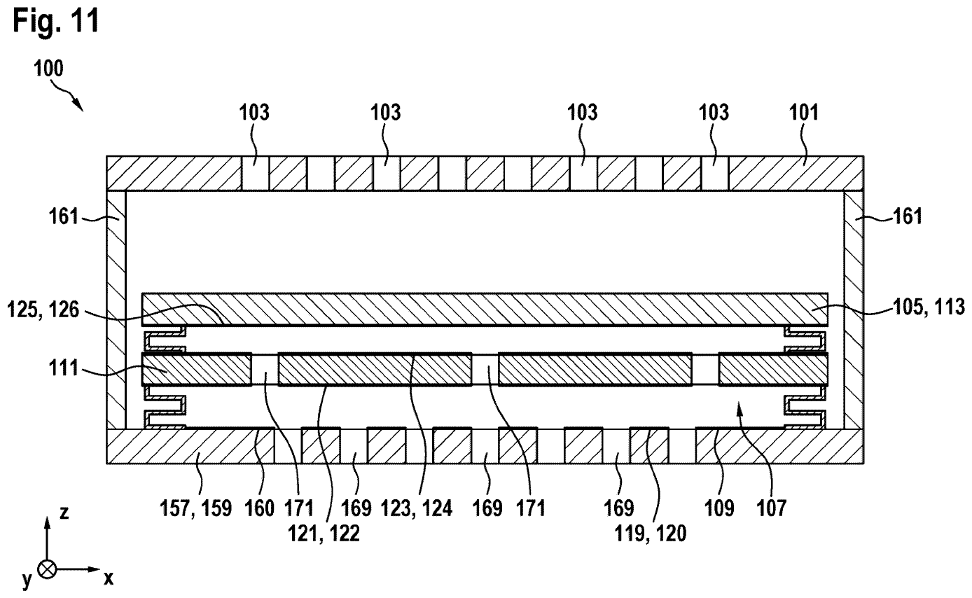

FIG. 11 shows a further schematic sectional view of a micromechanical loudspeaker 100 according to another embodiment. In the shown embodiment, the housing structure 101 comprises a plurality of outlet openings 103. The frame structure 157 further comprises a plurality of through-openings 169 in the bottom region 159.

In the shown embodiment, the actuator structure 107 comprises three actuator planes 109, 111, 113. The first actuator plane 109 is formed by the bottom surface 160 of the bottom region 159 of the frame structure 157. A further actuator plane 111 is resiliently connected to the frame structure 157 and likewise comprises a plurality of through-openings. A further actuator plane 113 is configured on a surface of the displacement surface 105 facing the actuator plane 111. The displacement plate 105 is resiliently connected to the actuator plane 111. The actuator plane 111 is resiliently connected to the actuator plane 109.

The actuator planes 109, 111, 113 comprise respective electrode units 120, 122, 124, 126.

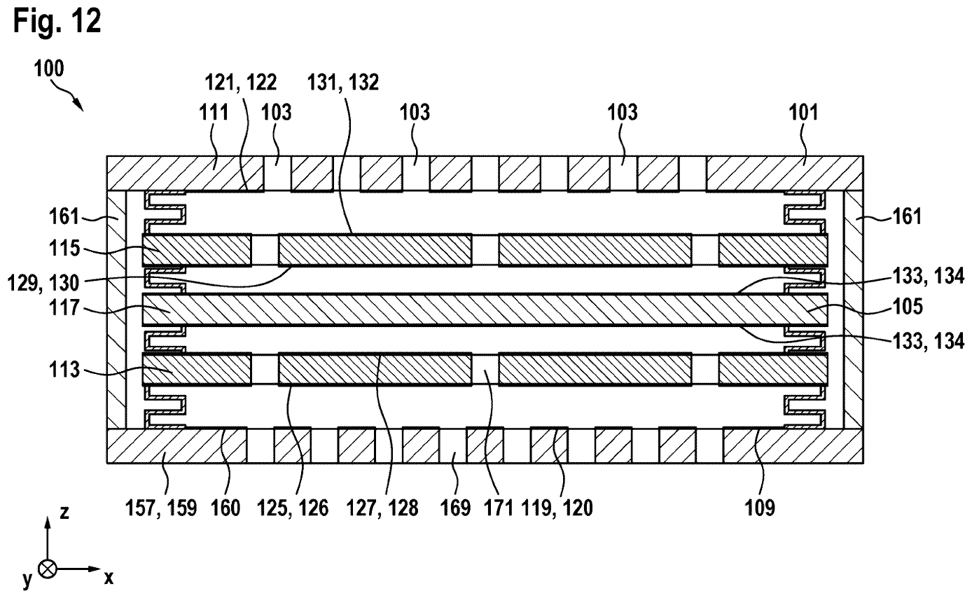

FIG. 12 shows a further schematic sectional view of a micromechanical loudspeaker 100 according to another embodiment. The shown embodiment is based on the embodiment in FIG. 11. In the shown embodiment, the actuator structure 107 comprises five actuator planes 109, 111, 113, 115, 117 that are resiliently connected to one another. The actuator planes 109, 111 are formed by planes of the frame structure 159 and are thus rigidly connected to one another. The corresponding spring elements are designed such that a volume between the actuator planes 111, 115, 117 and between the actuator planes 109, 113, 117 is laterally sealed. The displacement out of these volumes or the suction into these volumes caused by the actuation of the aforementioned actuator planes takes place via the openings 169, 171 in the actuator planes 115 and 111 on one side of the component and via the corresponding openings in the actuator planes 113 and 109 on the other side of the component. The actuator plane 109 is formed by the bottom surface 160 of the bottom region 159 of the frame structure 157. A further actuator plane 111 is formed by the housing structure 101. A respective further actuator plane 113, 115 is resiliently connected to the actuator plane 109 and the actuator plane 111. A further actuator plane 117 is formed by the displacement plate 105. The displacement plate is disposed between and resiliently connected to the actuator planes 113, 115. For this purpose, the displacement plate likewise comprises electrode units configured on two plane surfaces.

The number of actuator planes of the actuator structure 107 in the embodiments shown above is merely an example and can be configured otherwise. The structures of the actuator planes, the electrode units, and also the electrode projection elements on them, can moreover vary in terms of number or design. The configuration of the spring elements can furthermore vary as well.

The actuator structure 107 can be controlled by applying appropriate electrical voltages to the respective electrode units.

The displacement plate 105 and the actuator structure 107, in particular the actuator planes 109, 111, 113, 115 and 117, can in particular be made of a silicon material.

According to one embodiment, the electrode units can be configured as metal coatings and applied using a coating process.

1-16. (canceled)

17. A microelectromechanical loudspeaker, comprising:
a housing structure;
a displacement plate, which is mounted in the housing structure such that the displacement plate can be deflected along a deflection direction; and
an actuator structure, which is connected to the displacement plate for deflecting the displacement plate along the deflection direction, wherein the actuator structure includes at least two actuator planes which are resiliently connected to one another and disposed one above the other in the deflection direction, wherein, on facing plane surfaces, the actuator planes include electrode units, and wherein the electrode units can be activated to move the actuator planes relative to one another along the deflection direction, and the displacement plate can be deflected along the deflection direction via the movement of the actuator planes.

18. The loudspeaker according to claim 17, wherein the housing structure further includes an outlet opening which is disposed opposite to the displacement plate.

19. The loudspeaker according to claim 17, wherein at least one actuator plane of the actuator planes is configured as a flat plate, and wherein the electrode unit is configured as an electrode surface.

20. The loudspeaker according to claim 17, wherein each electrode unit includes at least one electrode projection element which projects from the plane surface along the deflection direction.

21. The loudspeaker according to claim 17, wherein the electrode units of the at least two actuator planes each include a plurality of electrode projection elements which are disposed in comb structures, and wherein the comb structures of the actuator planes are able to engage with one another.

22. The loudspeaker according to claim 21, wherein the electrode projection elements are configured as linear comb elements.

23. The loudspeaker according to claim 22, wherein the comb elements of each actuator plane extend in at least two extension directions which each have an angle to one another.

24. The loudspeaker according to claim 17, wherein at least one actuator plane of the actuator planes includes a spacer frame which is configured on an outer edge of the actuator plane, and wherein the actuator plane is resiliently connected to another of the actuator planes via at least one spring element configured on the spacer frame.

25. The loudspeaker according to claim 24, wherein each actuator plane is rectangular, and wherein a spring element is configured on each side edge of the actuator plane.

26. The loudspeaker according to claim 25, wherein the actuator planes have different dimensions and are disposed in a pyramidal arrangement along the deflection direction, and wherein the spring elements are disposed laterally on the side edges and can be deflected in the deflection direction and perpendicular to the deflection direction.

27. The loudspeaker according to claim 24, wherein the spacer frame includes a spacer element which extends along the deflection direction.

28. The loudspeaker according to claim 17, further comprising:
a frame structure, wherein the frame structure forms a receiving space, wherein the displacement plate and the actuator structure are disposed in the receiving space, and wherein an actuator plane is connected to the frame structure via at least one spring element.

29. The loudspeaker according to claim 28, wherein each actuator plane is formed by a bottom surface of a bottom region of the frame structure.

30. The loudspeaker according to claim 28, wherein an air gap is formed between an outer edge region of the displacement plate and wall elements of the frame structure.

31. The loudspeaker according to claim 29, wherein a respective through-opening is configured in at least one actuator plane and/or in the bottom region of the frame structure.

32. The loudspeaker according to claim 17, wherein the displacement plate is connected to one of the actuator planes via a connecting projection which extends along the deflection direction, and wherein a distance between the displacement plate and the actuator plane is defined via a length of the connecting projection.
